(19) United States
(12) Patent Application Publication
(10) Pub. No.: US 2010/0133654 A1
(43) Pub. Date: Jun. 3, 2010

(54) METHOD FOR MANUFACTURING CAPACITOR OF SEMICONDUCTOR

(76) Inventors: Hee Han, Daejeon Metropolitan City (KR); Kyung-Jun Kim, Daejeon Metropolitan City (KR); Byung-Kyu Choi, Seoul (KR)

Correspondence Address: MCKENNA LONG & ALDRIDGE LLP, 1900 K STREET, NW, WASHINGTON, DC, 20006, US

(21) Appl. No.: 12/452,139

(22) PCT Filed: Jun. 23, 2008
(86) PCT No.: PCT/KR2008/003553

§ 371 Date: Dec. 17, 2009

(30) Foreign Application Priority Data
Jun. 25, 2007 (KR) 10-2007-0062286

(51) Int. Cl. H01L 29/92; H01L 21/02; H01L 27/108

(52) U.S. Cl. 257/532; 438/387; 257/E29.342; 257/E21.011

(57) ABSTRACT

The present invention relates to a method of producing a semiconductor capacitor, and more particularly, to a method of producing a semiconductor capacitor, in which an electroless plating is performed during the production of a lower electrode to form a lower electrode.

### TECHNICAL FIELD

The present invention relates to a method of producing a semiconductor capacitor, and more particularly, to a method of producing a semiconductor capacitor, in which an electroless plating is performed during the production of a lower electrode to form a lower electrode.

This application claims priority from Korean Patent Application No. 10-2007-0062286 filed on Jun 25, 2007 in the KIPO, the disclosure of which is incorporated herein by reference in its entirety.

### BACKGROUND ART

A conventional method of producing a general semiconductor capacitor will be described with reference to FIG. 1.

After an interlayered insulating film 30 is formed on a semiconductor substrate 10 on which an active region 20 is formed, a contact hole that passes through the interlayered insulating film 30 and is connected to the active region 20 of a semiconductor substrate 10 is formed. Subsequently, the contact hole is filled with the conductive substance to form the contact plug 40. Subsequently, after a conductive film for a lower electrode 50 is formed and patterned, a dielectric thin film 60 and a conductive film for an upper electrode 70 are sequentially formed and patterned to form the capacitors 50, 60, and 70. Next, a capacitor insulating film 80 is formed.

The capacitance C of the semiconductor capacitor is defined by the following Equation 1.

C=ε·As/d [Equation 1]

wherein ε is dielectricity, As is an effective surface area of the electrode, and d is a distance between the electrodes.

According to an increase in integration of a semiconductor device to a 1 giga or more level, a high capacitance of a capacitor is required. Therefore, in order to increase the capacitance of the capacitor, a method of increasing an area of the lower electrode is used.

In the method of producing the semiconductor capacitor, polysilicon is conventionally used as the lower electrode, but in order to prevent deterioration of the lower electrode by an insulating body, it is changed into a TiN thin film. However, the TiN thin film has a high aspect ratio (AR) in order to increase an area ratio of the lower electrode. In a recent high integrated device, it is required that the capacity of the semiconductor capacitor is 30 fF per cell, and the aspect ratio is 20. Accordingly, because of the high aspect ratio of the TiN thin film, there is a problem in that while the semiconductor capacitor is produced, after the insulating film is etched, the lower electrode becomes inclined.

In addition, when polysilicon is conventionally used as the lower electrode, in order to increase the area, it is produced by using a method in which a hemisphere is subjected to the heat treatment as a seed to increase the area.

### DISCLOSURE OF INVENTION

### Technical Problem

Therefore, the present invention provides a method of producing a semiconductor capacitor, in which while a lower electrode is produced, an area of a lower electrode is increased to reduce an aspect ratio and improve the yield of a process.

### Technical Solution

In order to accomplish the above object, the present invention provides a method of producing a semiconductor capacitor that comprises preparing a substrate in which a contact plug is formed, forming a lower electrode, and forming a dielectric film and upper electrode, wherein the forming of the lower electrode comprises the steps of 1) forming a conductive film for the lower electrode by using a material for forming a conductive film for the lower electrode; 2) patterning the conductive film for the lower electrode of step 1); and 3) performing an electroless plating on the patterned conductive film for the lower electrode of step 2) to form the lower electrode.

In addition, the present invention provides a semiconductor capacitor that is produced by using the method of producing the semiconductor capacitor.

### Advantageous Effects

In a method of producing a semiconductor capacitor according to the present invention, since an area of a lower electrode is increased to reduce an aspect ratio of the lower electrode, the production yield of the semiconductor capacitor is capable of being increased and the production cost is capable of being reduced.

### BRIEF DESCRIPTION OF THE DRAWINGS

FIG. 1 is a process sectional view that illustrates a method of producing a capacitor of a semiconductor device according to a conventional technology;

FIG. 2 is a view that schematically illustrates a process for forming a lower electrode of a conventional semiconductor capacitor and a process for forming a lower electrode of a semiconductor capacitor according to an embodiment of the present invention;

FIG. 3 is a view that schematically illustrates a method of forming palladium (Pd) particles on a conductive film for a lower electrode according to an embodiment of the present invention; and

FIG. 4 is a view that illustrates a conventional TiN thin film and a TiN thin film to which a palladium (Pd) activation method is applied according to an embodiment of the present invention.

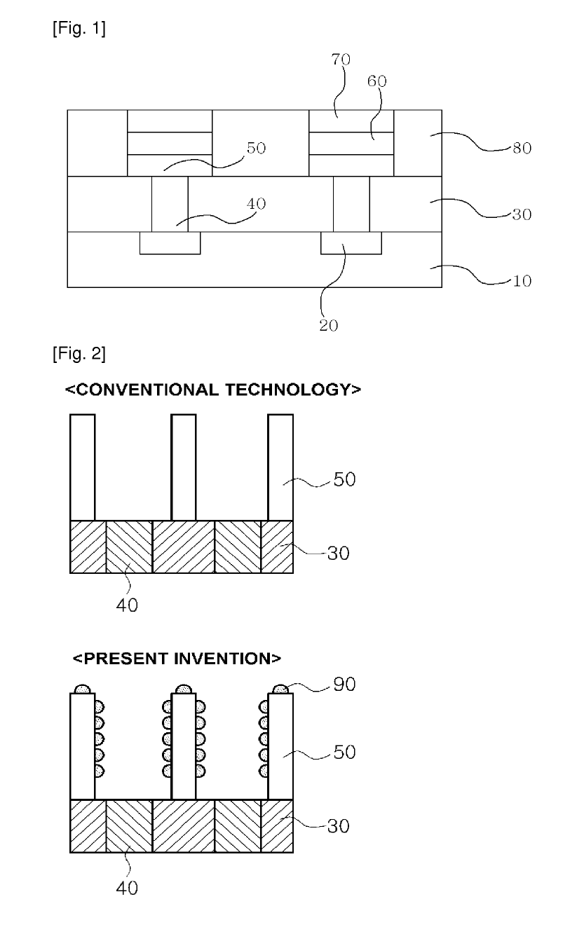

### REFERENCE NUMERALS

10: substrate

20: active region

30: interlayered insulating film

40: contact plug

50: conductive film for a lower electrode

60: dielectric thin film

70: conductive film for an upper electrode

80: capacitor insulating film

90: palladium particles

### Best Mode for Carrying out the Invention

Hereinafter, the present invention will be described in detail.

A method of producing a semiconductor capacitor according to the present invention comprises, while the lower electrode is formed, 1) forming a conductive film for the lower electrode by using a material for forming a conductive film for the lower electrode; 2) patterning the conductive film for the lower electrode of step 1); and 3) performing an electroless plating on the patterned conductive film for the lower electrode of step 2) to form the lower electrode.

In general, the electroless plating is a method in which metal ion in a plating solution is reduced using an electron generated while a reducing agent is oxidized in a solution on the catalyst to obtain a metal thin film.

In particular, in a method of producing a semiconductor capacitor according to the present invention, the electroless plating of step 3) may be performed by using a solution that includes palladium (Pd), ruthenium (Ru), platinum (Pt), or gold (Au) according to palladium activation method, ruthenium activation method, platinum activation method, or gold activation method in respects to the surface of the conductive film for the lower electrode.

Hereinafter, the palladium activation method will be mainly described, but the same manner may be applied in the ruthenium, platinum, or gold activation method.

In the present specification, the “palladium activation method” means a method in which the surface of the conductive film for the lower electrode is activated by using the solution that includes palladium, that is, the method in which the palladium particles are formed on the conductive film for the lower electrode through the substitution reaction.

In the method of producing the semiconductor capacitor according to the present invention, examples of palladium of step 3) may includes palladium chloride, palladium fluoride, bromopalladium, palladium iodide, palladium nitrate, palladium sulfate, palladium oxide, palladium sulfide, palladium cyanide, and palladium hexafluoroacetyl acetone, but are not limited thereto.

In addition, it is preferable that the content of palladium in the solution that includes palladium of step 3) is in the range of 0.01˜0.5 g/l.

It is known that the palladium activation method is used while the copper electroless plating is performed. However, in the present invention, the area of the lower electrode of the semiconductor capacitor is increased by using the palladium activation method and the like.

As the electroless plating using the palladium activation method according to the present invention, a detailed example for forming the lower electrode of the semiconductor capacitor is as follows.

First, in the electroless plating process, since a chemical state of the conductive film for the lower electrode plays an important role in the process, it is preferable that various impurities that are expected to be present on the conductive film for the lower electrode are previously removed. To be more specific, in order to remove Ti oxides and the like that may be present on the conductive film for the lower electrode, it is preferable to wash it using the HF solution. Next, the electroless plating using the palladium activation method using the solution that includes palladium, HF, and HCl may be performed to form the lower electrode of the semiconductor capacitor.

In the method of producing the semiconductor capacitor according to the present invention, the material for forming the conductive film for the lower electrode of step 1) is not limited, but may include TiN, Ta, TaN, TaSiN, or TiAlN.

In the method of producing the semiconductor capacitor according to the present invention, the forming of the conductive film for the lower electrode of step 1) may use the method that is selected from a Chemical Vapor Deposition (CVD) method, a Plasma-Enhanced Chemical Vapor Deposition (PECVD) method, a Sputtering method, an E-beam evaporation method, a Thermal evaporation method, a Laser Molecular Beam Epitaxy (L-MBE) method, a Pulsed Laser Deposition (PLD) method, and an Atomic layer deposition method.

In the method of producing the semiconductor capacitor according to the present invention, the patterning of the conductive film for the lower electrode of step 2) may use the method that is selected from a photolithography method, an offset printing method, a silkscreen printing method, an inkjet printing method, and a method using a Shadow Mask.

The method of producing the semiconductor capacitor according to the present invention may be performed by using a general method of producing that is known in the art, except that the electroless plating is performed to form the lower electrode.

To be more specific, the contact plug may be formed by using polysilicon and the like, the dielectric film may be formed by using a high dielectric film such as a NO₂ film, a Ta₂O₅ film, a TiO₂ film, and a BST film, and the upper electrode may be formed by using a metal material that includes a precious metal material such as ruthenium, platinum and the like, but not limited thereto. In addition, the dielectric film and the upper electrode may be formed by using a chemical deposition method, a plasma chemical deposition method, a Sputtering method, an E-beam evaporation method, a Thermal evaporation method, a Laser Molecular Beam Epitaxy method, a Pulsed Laser Deposition method, an Atomic layer deposition method, and the like, and may be patterned by using a photolithography method, an offset printing method, a silkscreen printing method, an inkjet printing method, a method using a Shadow Mask, and the like.

FIG. 2 is a view that schematically illustrates a process for forming a lower electrode of a conventional semiconductor capacitor and a process for forming a lower electrode of a semiconductor capacitor according to an embodiment of the present invention. Since the present invention may perform the electroless plating while the lower electrode is formed to form the palladium particles 90 on the conductive film for the lower electrode 50, the surface area of the lower electrode may be increased. In addition, the formed palladium particles 90 may act as an initial seed while the dielectric body is deposited to form an insulating film having a smooth surface.

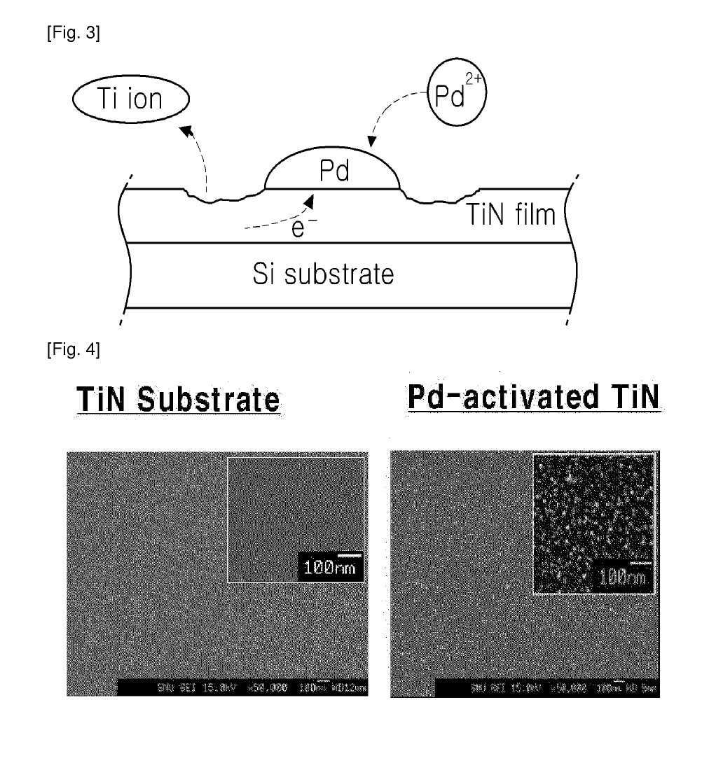

The method of forming the palladium (Pd) particles on the conductive film for the lower electrode that is an embodiment of the present invention is schematically illustrated in FIG. 3.

In addition, as the conductive film for the lower electrode, a conventional TiN thin film and a TiN thin film to which a palladium (Pd) activation method is applied according to an embodiment of the present invention are illustrated in FIG. 4.

The method of producing the semiconductor capacitor according to the present invention may increase the area of the lower electrode to reduce the aspect ratio of the lower electrode. In detail, nano particles such as hemisphere palladium are precipitated on the conductive film for the lower electrode by the palladium activation method and the like, and the lower electrode may have two or more times as large as the surface area of the conventional electrode. Thus, the effect in which the aspect ratio of the lower electrode is reduced by ½ or more may be obtained. Accordingly, finally, the production yield of the semiconductor capacitor can be increased and the production cost can be reduced.

In addition, the method of producing the semiconductor capacitor according to the present invention can form the insulating film that acts as the initial seed to have a smooth surface while the dielectric body is deposited by using the nano particles such as palladium, ruthenium, platinum, or gold according to the palladium activation method, can increase the density of the insulating film to prevent the leakage current, and increase the deposition rate of the insulating film because the initial nucleus generation rate becomes fast.

In addition, the present invention provides a semiconductor capacitor that is produced according to the method of producing the semiconductor capacitor.

Since the lower electrode of the semiconductor capacitor according to the present invention has the surface area that is two or more times as large as that of the conventional lower electrode, the aspect ratio of the lower electrode can be reduced by ½ or more.

1. A method of producing a semiconductor capacitor that comprises preparing a substrate in which a contact plug is formed, forming a lower electrode, and forming a dielectric film and an upper electrode,
wherein the forming of the lower electrode comprises the steps of:
1) forming a conductive film for the lower electrode by using a material for forming a conductive film for the lower electrode;
2) patterning the conductive film for the lower electrode of step 1); and
3) performing an electroless plating on the patterned conductive film for the lower electrode of step 2) to form the lower electrode.

2. The method of producing a semiconductor capacitor according to claim 1, wherein the electroless plating of step 3) is performed by using a solution that comprises palladium (Pd), ruthenium (Ru), platinum (Pt), or gold (Au) according to palladium activation method, ruthenium activation method, platinum activation method, or gold activation method in respects to the surface of the conductive film for the lower electrode.

3. The method of producing a semiconductor capacitor according to claim 1, wherein the electroless plating of step 3) is performed according to the palladium activation method using the solution that comprises palladium, HF, and HCl.

4. The method of producing a semiconductor capacitor according to claim 1, wherein palladium of step 3) comprises one or more that are selected from the group consisting of palladium chloride, palladium fluoride, bromopalladium, palladium iodide, palladium nitrate, palladium sulfate, palladium oxide, palladium sulfide, palladium cyanide, and palladium hexafluoroacetyl acetone.

5. The method of producing a semiconductor capacitor according to claim 1, wherein the content of palladium in the solution that comprises palladium of step 3) is in the range of 0.01˜0.5 g/l.

6. The method of producing a semiconductor capacitor according to claim 1, wherein the material for forming the conductive film for the lower electrode of step 1) comprises one or more that are selected from the group consisting of TiN, Ta, TaN, TaSiN, and TiAlN.

7. The method of producing a semiconductor capacitor according to claim 1, wherein the forming of the conductive film for the lower electrode of step 1) uses the method that is selected from the group consisting of a Chemical Vapor Deposition (CVD) method, a Plasma-Enhanced Chemical Vapor Deposition (PECVD) method, a Sputtering method, an E-beam evaporation method, a Thermal evaporation method, a Laser Molecular Beam Epitaxy (L-MBE) method, a Pulsed Laser Deposition (PLD) method, and an Atomic layer deposition method.

8. The method of producing a semiconductor capacitor according to claim 1, wherein the patterning of the conductive film for the lower electrode of step 2) uses the method that is selected from the group consisting of a photolithography method, an offset printing method, a silkscreen printing method, an inkjet printing method, and a method using a Shadow Mask.

9. A semiconductor capacitor that is produced by using the method of producing the semiconductor capacitor according to claim 1.

10. A semiconductor capacitor that is produced by using the method of producing the semiconductor capacitor according to claim 2.

11. A semiconductor capacitor that is produced by using the method of producing the semiconductor capacitor according to claim 3.

12. A semiconductor capacitor that is produced by using the method of producing the semiconductor capacitor according to claim 4.

13. A semiconductor capacitor that is produced by using the method of producing the semiconductor capacitor according to claim 5.

14. A semiconductor capacitor that is produced by using the method of producing the semiconductor capacitor according to claim 6.

15. A semiconductor capacitor that is produced by using the method of producing the semiconductor capacitor according to claim 7.

16. A semiconductor capacitor that is produced by using the method of producing the semiconductor capacitor according to claim 8.
